(19) United States
(12) Patent Application Publication
(10) Pub. No.: US 2020/0241123 A1
(43) Pub. Date: Jul. 30, 2020

(54) NONCONTACT VIBRATION SENSOR

(71) Applicant: Sil Radar Technology Inc., Kaohsiung City (TW)

(72) Inventors: Fu-Kang Wang, Kaohsiung City (TW); Sheng-You Tian, Kaohsiung City (TW)

(21) Appl. No.: 16/415,044

(22) Filed: May 17, 2019

(30) Foreign Application Priority Data
Jan. 30, 2019 (TW) 108103421

(51) Int. Cl. G01S 13/58; G01S 7/41

(52) U.S. Cl. CPC G01S 13/583; H03H 9/64; G01S 7/415

(57) ABSTRACT

A noncontact vibration sensor includes a wireless transceiver, a filter and an amplitude demodulator. The wireless transceiver is configured to transmit a transmission signal to an object and receive a reflected signal from the object. And the wireless transceiver is injection-locked by the reflected signal to output a self-injection-locked (SIL) signal. The filter is electrically connected to the wireless transceiver and configured to receive and convert the SIL signal from frequency modulation into amplitude modulation to output an amplitude-modulated signal. The amplitude demodulator is electrically connected to the filter and configured to receive and amplitude-demodulate the amplitude-modulated signal to output a demodulated signal.

### FIELD OF THE INVENTION

This invention generally relates to a vibration sensor, and more particularly to a noncontact vibration sensor.

### BACKGROUND OF THE INVENTION

Noncontact vibration sensors are widely researched due to they can be applied in long-distance vibration measurement. Generally, the noncontact vibration sensor may be direct-conversion radar or self-injection-locked radar. The self-injection-locked radar detects object vibrations by the Doppler effect in wireless signals and self-injection-locked oscillator and has highly sensitivity with respect to objection vibrations, as a result, it is suitable for detecting vital signs of life. Taiwan patents TW 1493213 (application no. 102116921) and TW 1495451 (application no. 101120769) disclose how to detect vital signs by using self-injection-locked radar. Briefly, the self-injection-locked radar is able to demodulate self-injection-locked signals in frequency by frequency demodulator to detect the vital signs.

### SUMMARY

The object of the present invention is to convert a self-injection-locked signal, which is output from a wireless transceiver, from frequency modulation into amplitude modulation by using a filter. Object vibrations can be sensed by amplitude-demodulating signals so as to simplify the architecture of demodulator in the noncontact vibration sensor.

A noncontact vibration sensor of the present invention comprises a wireless transceiver, a filter and an amplitude demodulator. The wireless transceiver is configured to transmit a transmission signal to an object and receive a reflected signal from the object. And the wireless transceiver is injection-locked by the reflected signal to output a self-injection-locked signal. The filter is electrically connected to the wireless transceiver and configured to receive the self-injection-locked signal and convert the self-injection-locked signal from frequency modulation into amplitude modulation to output an amplitude-modulated signal. The amplitude demodulator is electrically connected to the filter and configured to receive and amplitude-demodulate the amplitude-modulated signal to output a demodulated signal.

In the present invention, the self-injection-locked signal is converted from frequency modulation into amplitude modulation by the filter and amplitude-demodulated by the amplitude demodulator such that the architecture of demodulator in the noncontact vibration sensor is simplified.

### DESCRIPTION OF THE DRAWINGS

FIG. 1 is a functional block illustrating a noncontact vibration sensor in accordance with one embodiment of the present invention.

FIG. 2 is a circuit diagram illustrating a noncontact vibration sensor in accordance with a first embodiment of the present invention.

FIG. 3 is a circuit diagram illustrating a noncontact vibration sensor in accordance with a second embodiment of the present invention.

### DETAILED DESCRIPTION OF THE INVENTION

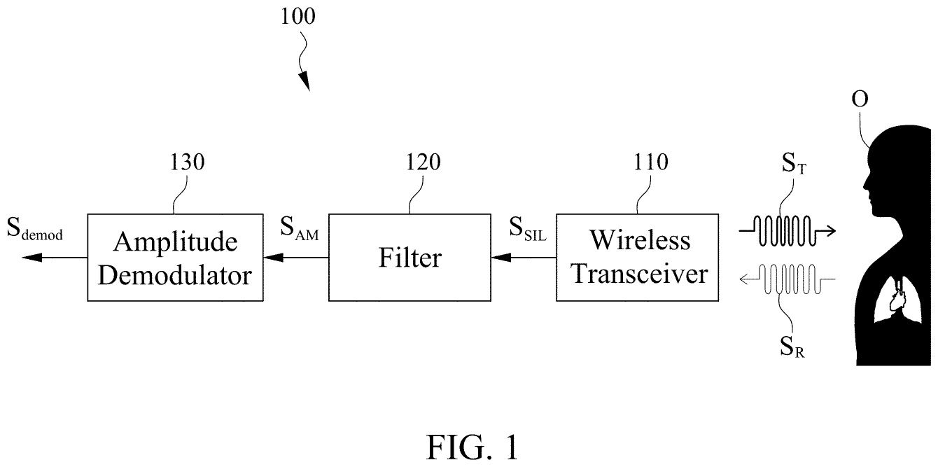

With reference to FIG. 1, a noncontact vibration sensor 100 in accordance with one embodiment of the present invention includes a wireless transceiver 110, a filter 120 and an amplitude demodulator 130. The filter 120 is electrically connected to the wireless transceiver 110 and the amplitude demodulator 130 is electrically connected to the filter 120. The wireless transceiver 110 may be a self-injection-locked wireless transceiver configured to transmit a transmission signal S_{T} to an object O, receive a reflected signal S_{R} from the object O and output a self-injection-locked signal S_{SIL} caused by injection-locking of the reflected signal S_{R}.

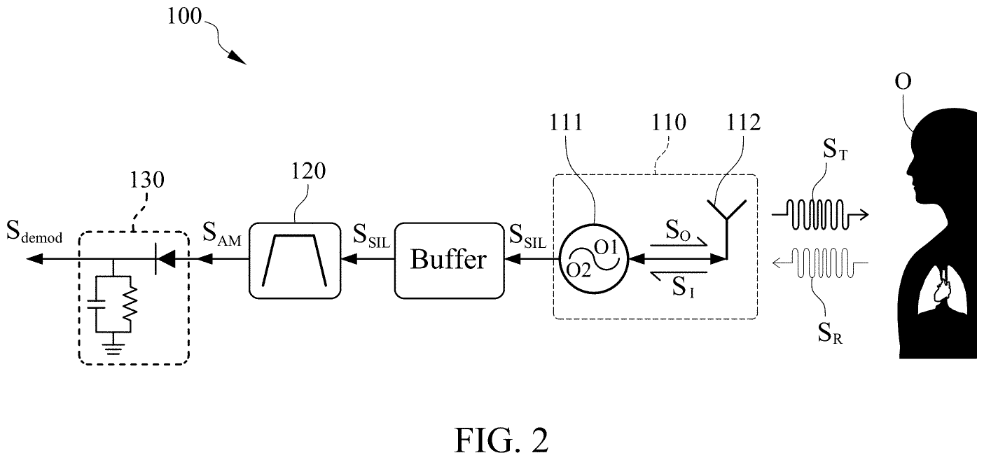

Motion of the object O relative the wireless transceiver 110 may result the Doppler effect in the transmission signal S_{T} such that the reflected signal S_{R} may contain Doppler phase shift components caused by motion of the object O. Accordingly, the frequency variation of the self-injection-locked signal S_{SIL} is proportional to the level of the Doppler phase shift when the wireless transceiver 110 is self-injection-locked by the reflected signal S_{R}. With reference to FIG. 2, the wireless transceiver 110 of a first embodiment of the present invention includes a self-injection-locked oscillator 111 and a transceiver antenna 112. The self-injection-locked oscillator 111 may be a voltage-controlled oscillator configured to receive an input voltage (not shown) and output an oscillation signal S_{O} whose center oscillation frequency is controlled by the input voltage. The transceiver antenna 112 is configured to receive the oscillation signal S_{O}, transmit the oscillation signal S_{O} to the object O as the transmission signal S_{T} and receive the reflected signal S_{R} from the object O as an injection signal S_{I}. The injection signal S_{I} may inject into and operate the self-injection-locked oscillator 111 in a self-injection-locked state. The transceiver antenna 112 may transmit and receive signals via a signal antenna or two different antennas.

With reference to FIG. 1, the filter 120, may be a low-pass filter, a pass-band filter or a high-band filter, is electrically connected to the wireless transceiver 110 for receiving the self-injection-locked signal S_{SIL}. With reference to FIG. 2, in the first embodiment, the filter 120 is a surface acoustic wave filter with a steep roll-off rate and the transmission signal S_{T} from the wireless transceiver 110 has a center oscillation frequency in a stop band of the filter 120. Meanwhile, the self-injection-locked signal S_{SIL} from the wireless transceiver 110 in the first embodiment also has a frequency variation caused by the Doppler phase shift of the reflected signal S_{R} in the stop band of the filter 120, such that the filter 120 can output signals having different amplitudes according to the frequency variation of the self-injection-locked signal S_{SIL} and convert the frequency variation into amplitude variation. Consequently, the filter 120 is capable of converting the self-injection-locked signal S_{SIL} from frequency modulation to amplitude modulation and outputting an amplitude-modulated signal S_{AM}. The filter 120 in the first embodiment preferably receives the self-injection-locked signal S_{SIL} from the wireless transceiver 110 via a buffer so as to prevent the filter 120 from reflecting signals to the wireless transceiver 110 to influence the self-injection-locking of the wireless transceiver 110.

With reference to FIG. 1, the amplitude demodulator 130 is electrically connected to the filter 120 for receiving the amplitude-modulated signal S_{AM} and configured to demodulate the amplitude-modulated signal S_{AM} in amplitude to output a demodulated signal S_{demod}. With reference to FIG. 2, the amplitude demodulator 130 is an envelope detector in the first embodiment. The amplitude demodulator 130 is provided to detect the power variation of the amplitude-modulated signal Se for amplitude demodulation and measure the motion of the object O relative to the wireless transceiver 110 to detect the vibration of the object O.

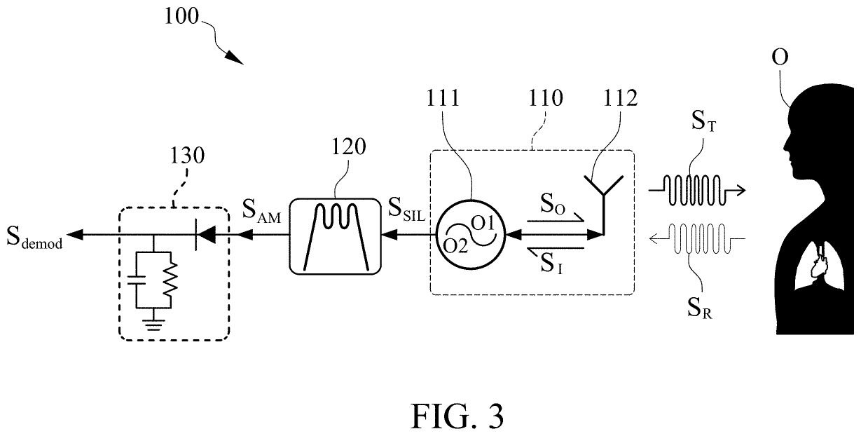

FIG. 3 represents a second embodiment of the present invention. As same as the first embodiment, the wireless transceiver 110 is a self-injection-locked wireless transceiver and the amplitude demodulator 130 is an envelope detector, but the filter 120 is a Chebyshev filter having ripples in a pass band. In the second embodiment, the transmission signal S_{T} has a center oscillation frequency in a pass band of the filter 120. Because of ripples in the pass band, the filter 120 is able to output signals having different amplitudes based on the frequency variation of the self-injection-locked signal S_{SIL} so that the frequency variation is converted into amplitude variation. Similarly, the filter 120 of the second embodiment is configured to convert the self-injection-locked signal S_{SIL} from frequency modulation to amplitude modulation and output the amplitude-modulated signal S_{AM}.

In the present invention, the self-injection-locked signal S_{SIL} is converted to amplitude modulation from frequency modulation by the filter 120 and amplitude-demodulated by the amplitude demodulator 130 such that the architecture of demodulator in the noncontact vibration sensor 100 is simplified.

The scope of the present invention is only limited by the following claims. Any alternation and modification without departing from the scope and spirit of the present invention will become apparent to those skilled in the art.

What is claimed is:

1. A noncontact vibration sensor, comprising:
a wireless transceiver configured to transmit a transmission signal to an object and receive a reflected signal from the object, the wireless transceiver is injection-locked by the reflected signal to output a self-injection-locked signal;
a filter electrically connected to the wireless transceiver and configured to receive the self-injection-locked signal and convert the self-injection-locked signal from frequency modulation to amplitude modulation to output an amplitude-modulated signal; and
an amplitude demodulator electrically connected to the filter and configured to receive the amplitude-modulated signal and amplitude-demodulate the amplitude-modulated signal to output a demodulated signal.

2. The noncontact vibration sensor in accordance with claim 1, wherein the transmission signal has a center oscillation frequency in a stop band of the filter.

3. The noncontact vibration sensor in accordance with claim 2, wherein the filter is a low-pass filter, a band-pass filter or a high-pass filter.

4. The noncontact vibration sensor in accordance with claim 1, wherein the filter has a steep roll-off rate.

5. The noncontact vibration sensor in accordance with claim 2, wherein the filter has a steep roll-off rate.

6. The noncontact vibration sensor in accordance with claim 3, wherein the filter has a steep roll-off rate.

7. The noncontact vibration sensor in accordance with claim 4, wherein the filter is a surface acoustic wave filter.

8. The noncontact vibration sensor in accordance with claim 5, wherein the filter is a surface acoustic wave filter.

9. The noncontact vibration sensor in accordance with claim 6, wherein the filter is a surface acoustic wave filter.

10. The noncontact vibration sensor in accordance with claim 1, wherein the filter has ripples in a pass band.

11. The noncontact vibration sensor in accordance with claim 10, wherein the filter is a Chebyshev filter.

12. The noncontact vibration sensor in accordance with claim 10, wherein the transmission signal has a center oscillation frequency in the pass band of the filter.

13. The noncontact vibration sensor in accordance with claim 11, wherein the transmission signal has a center oscillation frequency in the pass band of the filter.

14. The noncontact vibration sensor in accordance with claim 1, wherein the wireless transceiver includes a self-injection-locked oscillator and a transceiver antenna, the self-injection-locked oscillator is configured to generate an oscillation signal, the transceiver antenna is configured to receive and transmit the oscillation signal as the transmission signal and configured to receive the reflected signal as an injection signal, the injection signal is configured to inject into the self-injection-locked oscillator such that the self-injection-locked oscillator operates in a self-injection-locked state.

15. The noncontact vibration sensor in accordance with claim 1, wherein the amplitude demodulator is an envelope detector.
